(19) United States
(12) Patent Application Publication
(10) Pub. No.: US 2021/0359645 A1
(43) Pub. Date: Nov. 18, 2021

(54) CIRCUIT BOARD LAYOUT METHOD AND WIRING METHOD FOR CRYSTAL OSCILLATION CIRCUIT, AND CRYSTAL OSCILLATION CIRCUIT

(71) Applicant: PANASONIC INTELLECTUAL PROPERTY MANAGEMENT CO., LTD., Osaka (JP)

(72) Inventor: Toshinobu HATANO, Kanagawa (JP)

(73) Assignee: PANASONIC INTELLECTUAL PROPERTY MANAGEMENT CO., LTD., Osaka (JP)

(21) Appl. No.: 17/386,838

(22) Filed: Jul. 28, 2021

Related U.S. Application Data
(63) Continuation of application No. PCT/JP2019/038056, filed on Sep. 26, 2019.

(30) Foreign Application Priority Data
Jan. 29, 2019 (JP) 2019-013373

(51) Int. Cl. H03B 5/32; H03K 19/20

(52) U.S. Cl. CPC H03B 5/32; H03B 2200/0088; H03K 19/20

(57) ABSTRACT

A crystal oscillation circuit includes: two resistors; two capacitors; and an inverter. A crystal oscillation circuit for the crystal oscillation circuit includes: arranging the two resistors in parallel with the two capacitors such that an area of a wiring feedback path from an output terminal to an input terminal of the inverter is minimized, and arranging terminals of the two capacitors to be connected to ground close to each other.

### CROSS-REFERENCE TO RELATED APPLICATIONS

This application is a continuation of PCT International Patent Application No. PCT/JP2019/038056 filed on Sep. 26, 2019, which claims the benefit of priority of Japanese Patent Application No. 2019-013373 filed on Jan. 29, 2019, the entire contents of which are incorporated herein by reference.

### FIELD

The present disclosure relates to a circuit board layout method and a wiring method for a crystal oscillation circuit, and a crystal oscillation circuit used in an electronic device such as a camera.

### BACKGROUND

In recent years, in an automobile industry, sensing technology development for implementing autonomous driving has been booming. It is desirable that a camera, which is one of the sensing technologies, is not only small, but also can be attached in a free arrangement that emphasizes a design of a vehicle without being aware of an installation distance and a direction with respect to other electronic devices and antenna devices when mounting the camera on the vehicle.

A transmission method of an image signal of a camera is in transition from a conventional analog video signal output method to a high-speed serial digital signal output method that can stably output high-definition image information. In a camera application system, a low noise and noise resistance design in a high-frequency region associated with high-speed digital data transmission has become important. Further, as an operation quality requirement in a high-temperature environment of the vehicle increases and a size of the camera becomes smaller, countermeasures against heat against an increase in an internal temperature of the camera due to an actual operation of an electric circuit have become important together with a low noise and noise resistance design.

As a technology that can implement noise removal or noise reduction of an electronic device, for example, there are technologies disclosed in JP-B1-2980315 and JP-Y2-2597382. A wiring layout method and a wiring layout structure thereof described in JP-B1-2980315 include a positive-phase signal wiring and an intersection wiring that intersects the positive-phase signal wiring, and a signal wiring to which a signal having a phase opposite to that of the positive-phase signal wiring is applied is made to intersect the intersection wiring.

In a crystal oscillator described in JP-Y2-2597382, a crystal resonator is bridged and disposed, via a support body, on a circuit board on which a predetermined wiring including an output terminal is formed, and an IC chip in which an oscillation inverter and a buffer inverter are integrated, an input and output capacitor, and a feedback resistor are arranged so as to be connected to the crystal resonator. In the crystal oscillator in which an oscillation output of the buffer inverter is derived from an output terminal, the input and output capacitor and the feedback resistor are arranged on the circuit board below the crystal resonator, and the IC chip is disposed in the vicinity of the output terminal.

### SUMMARY

However, in the wiring layout method and the wiring layout structure thereof described in JP-B1-2980315, an effect is limited to adding an electromagnetic noise of an output inversion signal to an electromagnetic noise of the intersection wiring orthogonal to the positive-phase signal wiring so as to cancel the electromagnetic noise.

In the crystal oscillator described in JP-Y2-2597382, since a distance of an output wiring of the IC chip is shortened, a noise generated inside the oscillator and increased due to high-frequency oscillation and a high load is reduced, and a crystal oscillator with few oscillation abnormalities can be implemented, but optimization of a flow path of a current that flows through a capacitor is not mentioned.

The present disclosure has been made in view of the above circumstances, and an object thereof is to provide a circuit board layout method and a wiring method for a crystal oscillation circuit, and a crystal oscillation circuit capable of optimizing a path of a current that flows through a capacitor that constitutes the crystal oscillation circuit, and further reducing an electromagnetic noise.

The present disclosure provides a circuit board layout method for a crystal oscillation circuit, the crystal oscillation circuit including a crystal resonator, a first resistor, a second resistor, a first capacitor, a second capacitor, and an inverter, wherein one end of the crystal resonator, an input end of the inverter, one end of the first resistor, and one end of the first capacitor are commonly connected, an output end of the inverter, another end of the first resistor, and one end of the second resistor are commonly connected, another end of the crystal resonator, another end of the second resistor, and one end of the second capacitor are commonly connected, and another end of the first capacitor and another end of the second capacitor are grounded, the circuit board layout method including: arranging the first resistor and the second resistor in parallel with the first capacitor and the second capacitor such that an area of a wiring feedback path from an output terminal to an input terminal of the inverter is minimized; and arranging terminals of the first capacitor and the second capacitor to be connected to ground close to each other.

The present disclosure provides a wiring method for a crystal oscillation circuit, the crystal oscillation circuit having a layout by the circuit board layout method, wherein the first resistor and the second resistor are arranged in parallel with the first capacitor and the second capacitor such that the area of the wiring feedback path from the output terminal to the input terminal of the inverter is minimized, and the terminals of the first capacitor and the second capacitor to be connected to ground are arranged close to each other, the wiring method including: mounting components including the crystal resonator, the first resistor, the second resistor, the first capacitor, and the second capacitor on a surface layer of a multilayer circuit board; and wiring all inter-component-terminal wirings in an inner layer of the multilayer circuit board.

The present disclosure provides a crystal oscillation circuit including: a crystal resonator; a first resistor; a second resistor; a first capacitor; a second capacitor; and an inverter, wherein one end of the crystal resonator, an input end of the inverter, one end of the first resistor, and one end of the first capacitor are commonly connected, wherein an output end of the inverter, another end of the first resistor, and one end of the second resistor are commonly connected, wherein another end of the crystal resonator, another end of the second resistor, and one end of the second capacitor are commonly connected, and another end of the first capacitor and another end of the second capacitor are grounded, wherein the first resistor and the second resistor are arranged in parallel with the first capacitor and the second capacitor such that an area of a wiring feedback path from an output terminal to an input terminal of the inverter is minimized, and wherein terminals of the first capacitor and the second capacitor to be connected to ground are arranged close to each other.

According to the present disclosure, a path of a current that flows to ground via a capacitor that constitutes a crystal oscillation circuit is optimized, and an electromagnetic noise is further reduced.

### BRIEF DESCRIPTION OF DRAWINGS

FIG. 1 is a circuit diagram showing a crystal oscillation circuit according to an embodiment of the present disclosure.

FIG. 2 is an illustrative diagram showing a circuit board layout of the crystal oscillation circuit of FIG. 1.

FIG. 3 is a diagram showing a relationship among sizes of a crystal resonator, two resistors, and two capacitors of the crystal oscillation circuit of FIG. 1.

FIG. 4 is an illustrative diagram showing a circuit board layout of a crystal oscillation circuit that leads to the embodiment of the present disclosure.

FIG. 5 is an illustrative diagram showing a circuit board layout of a crystal oscillation circuit that leads to the embodiment of the present disclosure.

### DETAILED DESCRIPTION

First, circumstances that lead to an embodiment of the present disclosure will be described.

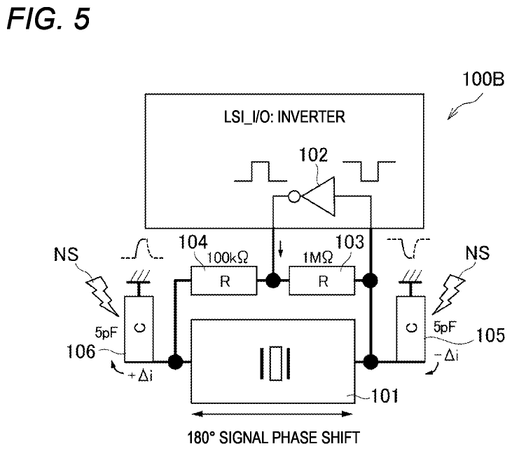

FIGS. 4 and 5 are illustrative diagrams of circuit board layouts of crystal oscillation circuits that lead to the embodiment of the present disclosure. A crystal oscillation circuit 100A shown in FIG. 4 and a crystal oscillation circuit 100B shown in FIG. 5 both include a crystal resonator 101, an inverter 102, a resistor (a first resistor) 103, a resistor (a second resistor) 104, a capacitor (a first capacitor) 105, and a capacitor (a second capacitor) 106. One end of the crystal resonator 101, an input end of the inverter 102, one end of the resistor 103, and one end of the capacitor 105 are commonly connected. An output end of the inverter 102, the other end of the resistor 103, and one end of the resistor 104 are commonly connected. The other end of the crystal resonator 101, the other end of the resistor 104, and one end of the capacitor 106 are commonly connected. The other ends of the two capacitors 105 and 106 are grounded.

Here, the resistor 103 interposed between input and output ends of the inverter 102 is referred to as a feedback resistor. Further, when the inverter 102 is configured with a complementary metal oxide semiconductor (CMOS), the resistor 104 is referred to as a drain resistor, the capacitor 105 is referred to as a drain capacitance, and the capacitor 106 is referred to as a gate capacitance.

In a layout of a circuit board of components that constitute the crystal oscillation circuit 100A, the resistors 103 and 104 are linearly arranged and arranged in parallel with the crystal resonator 101. The inverter 102 is disposed in parallel with the resistor 103. The capacitors 105 and 106 are arranged linearly with the crystal resonator 101. On the other hand, in a layout of a circuit board of components that constitute a crystal oscillation circuit 100B, the resistors 103 and 104 are linearly arranged and arranged in parallel with the crystal resonator 101, the inverter 102 is disposed in parallel with the resistor 103, and the capacitors 105 and 106 are arranged in a direction perpendicular to a longitudinal direction of the crystal resonator 101.

In the crystal oscillation circuits 100A and 100B, in a current feedback path of the capacitors where a minute current change (a Δi change) occurs with respect to ground, polarities of minute currents −Δi and +Δi that flow through the capacitors 105 and 106 are in an inverted relationship with each other. The minute current −Δi that flows through the capacitor 105 flows in a direction from a ground side to a crystal resonator 101 side, and the minute current +Δi that flows through the capacitor 106 flows in a direction from the crystal resonator 101 side to the ground side. When the minute currents +Δi and −Δi flow, an electromagnetic noise NS is generated. If these minute currents +Δi and −Δi can be suppressed, the electromagnetic noise NS can be reduced. The present disclosure can cancel the minute currents +Δi and −Δi, so that the electromagnetic noise NS can be reduced.

Hereinafter, a preferred embodiment for carrying out the present disclosure will be described in detail with reference to the drawings.

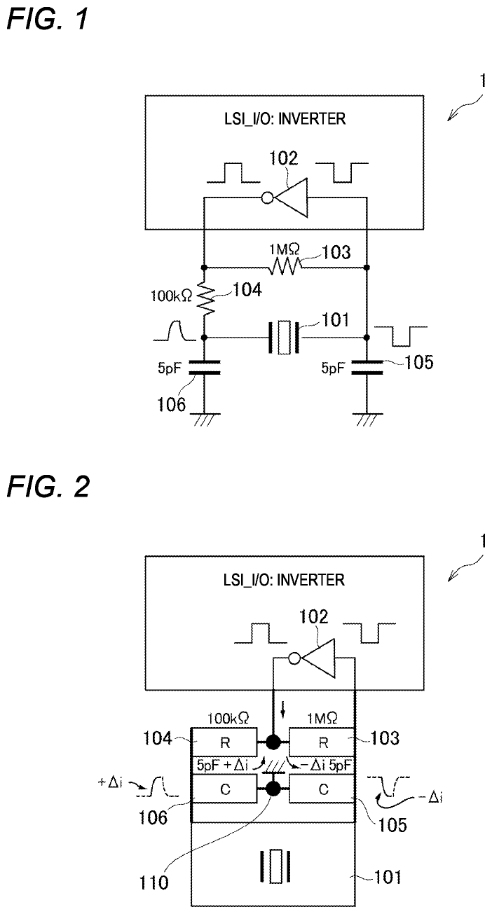

FIG. 1 is a circuit diagram showing a crystal oscillation circuit 1 according to an embodiment of the present disclosure. FIG. 2 is an illustrative diagram showing a layout of components that constitute the crystal oscillation circuit 1 of FIG. 1. First, in FIG. 1, the crystal oscillation circuit 1 includes the crystal resonator 101, the inverter 102, the two resistors 103 and 104, and the two capacitors 105 and 106. Regarding connection of the components, one end of the crystal resonator 101, an input end of the inverter 102, one end of the resistor 103, and one end of the capacitor 105 are commonly connected; an output end of the inverter 102, the other end of the resistor 103, and one end of the resistor 104 are commonly connected; the other end of the crystal resonator 101, the other end of the resistor 104, and one end of the capacitor 106 are commonly connected; and the other ends of the capacitors 105 and 106 are grounded.

In a circuit board layout of the components that constitute the crystal oscillation circuit 1, input and output wirings of the inverter 102 are parallel wirings, the resistors 103 and 104 and the capacitors 105 and 106 are linearly arranged, and the resistors 103 and 104 are arranged in parallel with the capacitors 105 and 106. The resistor 103 is positioned between parallel wirings of the input and output wirings of the inverter 102. The crystal resonator 101 is disposed in parallel with the capacitors 105 and 106 on a side opposite to the resistors 103 and 104 across the capacitors 105 and 106.

The crystal oscillation circuit 1 according to the present embodiment has the same circuit configuration as those of the crystal oscillation circuits 100A and 100B that lead to the embodiment of the present disclosure, but there is a difference in the layout of the components. That is, in the crystal oscillation circuit 1 according to the present embodiment, the input and output wirings of the inverter 102 are the parallel wirings, the two resistors 103 and 104 are arranged in parallel with the two capacitors 105 and 106 so that an area of a wiring feedback path from an output terminal to an input terminal of the inverter 102 is minimized, and terminals of the two capacitors 105 and 106 to be connected to the ground are arranged close to each other.

In this way, the layout minimizes the area of the wiring feedback path from the output terminal to the input terminal of the inverter 102, and the terminals of the two capacitors 105 and 106 to be connected to the ground are arranged close to each other, so that in a capacitor current feedback path where the minute current change (the Δi change) occurs with respect to the ground, polarities of minute currents that flow through the two capacitors 105 and 106 are in an inverted relationship with each other, and the minute currents flow in opposite directions. Therefore, the currents can be canceled by a common ground terminal portion 110. That is, since the minute currents +Δi and −Δi can be canceled, the electromagnetic noise NS can be reduced.

The two resistors 103 and 104 are arranged in parallel with the two capacitors 105 and 106 so as to have the layout in which the area of the wiring feedback path from the output terminal to the input terminal of the inverter 102 is minimized, so that a feedback current in an oscillation operation can be reduced.

Components of the crystal resonator 101, the two resistors 103 and 104, and the two capacitors 105 and 106 that constitute the crystal oscillation circuit 1 according to the present embodiment are mounted on a surface layer of a multilayer circuit board (not shown), and all inter-component-terminal wirings are wired in an inner layer of the multilayer circuit board.

With such a component layout and wiring, radiation of the electromagnetic noise to an outside of the circuit board due to the Δi change and the Av change generated in the inter-component-terminal wiring can be suppressed inside the circuit board. That is, the electromagnetic noise can be effectively absorbed by a ground potential.

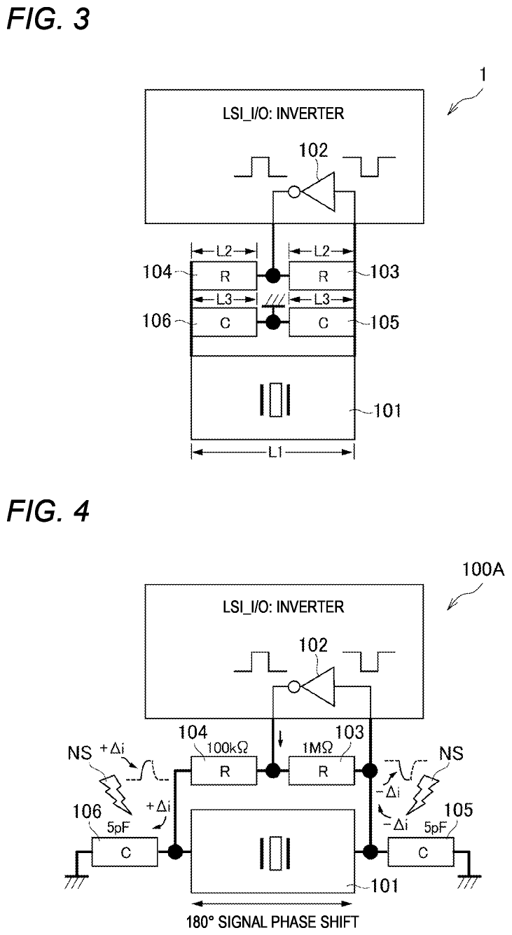

In the crystal oscillation circuit 1 according to the present embodiment, it is desirable that component sizes of the two resistors 103 and 104 and the two capacitors 105 and 106 are equal to or smaller than a component size of the crystal resonator 101. For example, as shown in FIG. 3, a length L2 of a long side of each of the two resistors 103 and 104 and a length L3 of a long side of each of the two capacitors 105 and 106 are set to be equal to or smaller than ½ of a length L1 of a long side of the crystal resonator 101.

As described above, according to the crystal oscillation circuit 1 of the present embodiment, in the layout when the components that constitute the crystal oscillation circuit 1 are mounted on the circuit board, the two resistors 103 and 104 are arranged in parallel with the two capacitors 105 and 106 so that the area of the wiring feedback path from the output terminal to the input terminal of the inverter 102 is minimized, and the terminals of the two capacitors 105 and 106 to be connected to the ground are arranged close to each other, so that the minute currents −Δi and +Δi that flow through the two capacitors 105 and 106 can be canceled. Therefore, the electromagnetic noise NS can be reduced. Further, the two resistors 103 and 104 are arranged in parallel with the two capacitors 105 and 106 so as to have the layout in which the area of the wiring feedback path from the output terminal to the input terminal of the inverter 102 is minimized, so that a feedback current loop in an oscillation operation can be reduced.

According to the crystal oscillation circuit 1 of the present embodiment, the components of the crystal resonator 101, the two resistors 103 and 104, and the two capacitors 105 and 106 are mounted on the surface layer of the multilayer circuit board, and all inter-component-terminal wirings are wired in the inner layer of the multilayer circuit board. Therefore, radiation of the electromagnetic noise to an outside of the circuit board due to the Δi change and the Av change generated in the inter-component-terminal wiring can be suppressed inside the circuit board. That is, the electromagnetic noise can be effectively absorbed by the ground potential.

In this way, in the crystal oscillation circuit 1 according to the present embodiment, the electromagnetic noise is minimized. Therefore, it is possible to implement, for example, a small camera that is free to be installed in a vehicle and has excellent low noise and noise resistance performance.

The present disclosure provides a wiring method for a crystal oscillation circuit, the crystal oscillation circuit having a layout by the circuit board layout method, wherein the first resistor and the second resistor are arranged in parallel with the first capacitor and the second capacitor such that the area of the wiring feedback path from the output terminal to the input terminal of the inverter is minimized, and the terminals of the first capacitor and the second capacitor to be connected to ground are arranged close to each other, the wiring method including: mounting components including the crystal resonator, the first resistor, the second resistor, the first capacitor, and the second capacitor on a surface layer of a multilayer circuit board; and wiring all inter-component-terminal wirings in an inner layer of the multilayer circuit board.

According to the above method, the layout minimizes the area of the wiring feedback path from the output terminal to the input terminal of the inverter, and the terminals of the two capacitors to be connected to the ground are arranged close to each other, so that in a capacitor current feedback path where a minute current change (a Δi change) occurs with respect to the ground, polarities of minute currents that flow through the two capacitors are in an inverted relationship with each other, and the minute currents flow in opposite directions. Therefore, the currents can be canceled by a common ground terminal portion.

The two resistors are arranged in parallel with the two capacitors so as to have the layout in which the area of the wiring feedback path from the output terminal to the input terminal of the inverter is minimized, so that a feedback current in an oscillation operation can be reduced.

The present disclosure provides a crystal oscillation circuit including: a crystal resonator; a first resistor; a second resistor; a first capacitor; a second capacitor; and an inverter, wherein one end of the crystal resonator, an input end of the inverter, one end of the first resistor, and one end of the first capacitor are commonly connected, wherein an output end of the inverter, another end of the first resistor, and one end of the second resistor are commonly connected, wherein another end of the crystal resonator, another end of the second resistor, and one end of the second capacitor are commonly connected, and another end of the first capacitor and another end of the second capacitor are grounded, wherein the first resistor and the second resistor are arranged in parallel with the first capacitor and the second capacitor such that an area of a wiring feedback path from an output terminal to an input terminal of the inverter is minimized, and wherein terminals of the first capacitor and the second capacitor to be connected to ground are arranged close to each other.

According to the above method, radiation of an electromagnetic noise to an outside of the circuit board due to a Δi change and a Δv change generated in an inter-component-terminal wiring can be suppressed inside the circuit board. That is, the electromagnetic noise can be effectively absorbed by a ground potential.

Although the present disclosure has been described in detail with reference to a specific embodiment, it will be apparent to those skilled in the art that various changes and modifications can be made without departing from the spirit and the scope of the present disclosure.

The present application is based on Japanese Patent Application (Japanese Patent Application No. 2019-013373) filed on Jan. 29, 2019, and the contents of which are incorporated herein by reference.

The present disclosure is useful for a small camera that is free to be installed in a vehicle and has excellent low noise and noise resistance performance.

1. A circuit board layout method for a crystal oscillation circuit, the crystal oscillation circuit comprising a crystal resonator, a first resistor, a second resistor, a first capacitor, a second capacitor, and an inverter, wherein one end of the crystal resonator, an input end of the inverter, one end of the first resistor, and one end of the first capacitor are commonly connected, an output end of the inverter, another end of the first resistor, and one end of the second resistor are commonly connected, another end of the crystal resonator, another end of the second resistor, and one end of the second capacitor are commonly connected, and another end of the first capacitor and another end of the second capacitor are grounded, the circuit board layout method comprising:
arranging the first resistor and the second resistor in parallel with the first capacitor and the second capacitor such that an area of a wiring feedback path from an output terminal to an input terminal of the inverter is minimized; and
arranging terminals of the first capacitor and the second capacitor to be connected to ground close to each other.

2. The circuit board layout method according to claim 1, comprising:
arranging the first resistor between parallel wirings comprising an input wiring and an output wiring of the inverter.

3. The circuit board layout method according to claim 1, comprising:
arranging the first resistor and the second resistor linearly.

4. The circuit board layout method according to claim 1, comprising:
arranging the first capacitor and the second capacitor linearly.

5. The circuit board layout method according to claim 4, comprising:
arranging the another end of the first resistor and the another end of the second resistor to face a common ground terminal portion.

6. The circuit board layout method according to claim 1, comprising
arranging the crystal resonator in parallel with the first capacitor and the second capacitor on a side opposite to the first resistor and the second resistor across the first capacitor and the second capacitor.

7. A wiring method for a crystal oscillation circuit, the crystal oscillation circuit having a layout by the circuit board layout method according to claim 1, wherein the first resistor and the second resistor are arranged in parallel with the first capacitor and the second capacitor such that the area of the wiring feedback path from the output terminal to the input terminal of the inverter is minimized, and the terminals of the first capacitor and the second capacitor to be connected to ground are arranged close to each other, the wiring method comprising:
mounting components comprising the crystal resonator, the first resistor, the second resistor, the first capacitor, and the second capacitor on a surface layer of a multilayer circuit board; and
wiring all inter-component-terminal wirings in an inner layer of the multilayer circuit board.

8. The wiring method according to claim 7,
wherein a component size of each of the first resistor, the second resistor, the first capacitor, and the second capacitor is equal to or smaller than a component size of the crystal resonator.

9. A crystal oscillation circuit comprising:
a crystal resonator;
a first resistor;
a second resistor;
a first capacitor;
a second capacitor;
and an inverter,
wherein one end of the crystal resonator, an input end of the inverter, one end of the first resistor, and one end of the first capacitor are commonly connected,
wherein an output end of the inverter, another end of the first resistor, and one end of the second resistor are commonly connected,
wherein another end of the crystal resonator, another end of the second resistor, and one end of the second capacitor are commonly connected, and another end of the first capacitor and another end of the second capacitor are grounded,
wherein the first resistor and the second resistor are arranged in parallel with the first capacitor and the second capacitor such that an area of a wiring feedback path from an output terminal to an input terminal of the inverter is minimized, and
wherein terminals of the first capacitor and the second capacitor to be connected to ground are arranged close to each other.

10. The crystal oscillation circuit according to claim 9,
wherein an input wiring and an output wiring of the inverter are parallel wirings.

11. The crystal oscillation circuit according to claim 9,
wherein the first resistor is arranged between the parallel wirings of the inverter.

12. The crystal oscillation circuit according to claim 9,
wherein the first resistor and the second resistor are linearly arranged.

13. The crystal oscillation circuit according to claim 9,
wherein the first capacitor and the second capacitor are linearly arranged.

14. The crystal oscillation circuit according to claim 13,
wherein the another end of the first resistor and the another end of the second resistor are arranged to face a common ground terminal portion.

15. The crystal oscillation circuit according to claim 14,
wherein the another end of the first resistor and the another end of the second resistor are connected to the common ground terminal portion.

16. The crystal oscillation circuit according to claim 9,
wherein the crystal resonator is arranged in parallel with the first capacitor and the second capacitor on a side opposite to the first resistor and the second resistor across the first capacitor and the second capacitor.

17. The crystal oscillation circuit according to claim 9, further comprising:
a multilayer circuit board,
wherein components comprising the crystal resonator, the first resistor, the second resistor, the first capacitor, and the second capacitor are mounted on a surface layer of the multilayer circuit board; and
wherein all inter-component-terminal wirings are wired in an inner layer of the multilayer circuit board.

18. The crystal oscillation circuit according to claim 9,
wherein a component size of each of the first resistor, the second resistor, the first capacitor, and the second capacitor is equal to or smaller than a component size of the crystal resonator.

19. The crystal oscillation circuit according to claim 18,
wherein a length of a long side of each of the first resistor and the second resistor is equal to or smaller than a half of a length of a long side of the crystal resonator.

20. The crystal oscillation circuit according to claim 18,
wherein a length of a long side of each of the first capacitor and the second capacitor is equal to or smaller than a half of a length of a long side of the crystal resonator.
